(19) United States
(12) Patent Application Publication
(10) Pub. No.: US 2023/0398627 A1
(43) Pub. Date: Dec. 14, 2023

(54) LASER OSCILLATOR AND LASER PROCESSING SYSTEM

(71) Applicant: Panasonic Intellectual Property Management Co., Ltd., Osaka (JP)

(72) Inventors: YUJI ISOMOTO, Shiga (JP); KENKI KOYAMA, Osaka (JP)

(21) Appl. No.: 18/454,235

(22) Filed: Aug. 23, 2023

Related U.S. Application Data
(63) Continuation of application No. PCT/JP2022/008946, filed on Mar. 2, 2022.

(30) Foreign Application Priority Data
Mar. 4, 2021 (JP) 2021-034471

(51) Int. Cl. B23K 26/0622

(52) U.S. Cl. CPC B23K 26/0622

(57) ABSTRACT

Laser oscillator (10) includes semiconductor laser light source (21), drive power source (22) that drives the semiconductor laser light source with voltage of capacitor (24) charged, switch unit (23) that switches a voltage supply state from external power source (40) to the capacitor, and controller (30) that controls switching of the switch unit. The controller has a model representing a known relationship between a discharge time that is an elapsed time after supply of voltage from the external power source to the capacitor is stopped, and a required preliminary-charge time that is a time required for the capacitor to obtain a shortage of voltage required to drive the semiconductor laser light source. The controller derives the required preliminary-charge time from the discharge time based on the model to perform mode switching from the stop mode to the preliminary-charge mode, and then performs mode switching from the preliminary-charge mode to the drive mode after the required preliminary-charge time elapses.

### TECHNICAL FIELD

The present disclosure relates to a laser oscillator and a laser processing system.

### BACKGROUND ART

A laser oscillator is a device that oscillates a laser beam, and is mounted on a laser processing system, for example, and used to perform laser processing such as cutting, welding, and punching of a workpiece.

The laser processing apparatus disclosed in PTL 1 includes a power source (drive power source), a laser excitation light source (semiconductor laser light source), and a laser excitation light source condenser. The laser excitation light source is composed of multiple semiconductor laser diode elements arranged linearly. The power source serves as a constant voltage power source to apply predetermined voltage to the laser excitation light source. As a result, laser oscillation occurs in each element of the laser excitation light source. The laser oscillation is condensed by the laser excitation light source condenser to be output as laser excitation light.

### CITATION LIST

### Patent Literature

PTL 1: Unexamined Japanese Patent Publication No. 2013-240834

### SUMMARY OF THE INVENTION

### Technical Problem

The laser oscillator includes the drive power source for driving the semiconductor laser light source, the drive power source usually incorporating a capacitor, and voltage of the capacitor charged is applied to the semiconductor laser light source to cause the semiconductor laser light source to emit a laser beam. The voltage (power) is supplied to the drive power source by an external power source different from the drive power source.

From the viewpoint of ensuring safety and the like, a laser processing step requires the laser oscillator to be emergently stopped every time one workpiece is processed (for each processing). The laser oscillator is emergently stopped by stopping the supply of voltage from the external power source to the drive power source.

When the laser oscillator is emergently stopped, the voltage of the capacitor in the drive power source decreases due to discharge. To recover the laser oscillator from the emergency stop to bring the semiconductor laser light source into a drivable state, the capacitor of the drive power source is required to be preliminarily charged to recover the voltage lowered.

Thus, the laser processing step is required to secure a preliminary charge time for recovering the laser oscillator from the emergency stop for each processing. This requirement causes increase in cycle time of the laser processing step.

The present disclosure is made in view of such a point, and a main object thereof is to shorten a recovery time from an emergency stop of a laser oscillator.

### Solution to Problem

A laser oscillator according to the present disclosure includes: a semiconductor laser light source that emits a laser beam; a drive power source that include a capacitor to which voltage is supplied from an external power source, and that drives the semiconductor laser light source with voltage of the capacitor charged; a switch unit that switches a voltage supply state from the external power source to the capacitor; and a controller that controls switching of the switch unit. The controller is configured as follows: performing mode switching among a drive mode in which the semiconductor laser light source is drivable, a preliminary-charge mode in which the capacitor is preliminarily charged, and a stop mode in which supply of voltage from the external power source to the capacitor is stopped; having a model showing a known relationship between a discharge time that an elapsed time from stop of supply of voltage from the external power source to the capacitor and a required preliminary-charge time that is required for the capacitor to obtain a shortage of voltage required to drive the semiconductor laser light source; and deriving the required preliminary-charge time from the discharge time based on the model to perform mode switching from the stop mode to the preliminary-charge mode, and then performing mode switching from the preliminary-charge mode to the drive mode after the required preliminary-charge time elapses.

A laser processing system according to the present disclosure includes the laser oscillator and a laser irradiation head that irradiates a workpiece with a laser beam emitted from the laser oscillator.

### Advantageous Effect of Invention

The present disclosure enables shortening a recovery time from an emergency stop of a laser oscillator.

### BRIEF DESCRIPTION OF THE DRAWINGS

FIG. 1 is a diagram schematically illustrating a laser processing system including a laser oscillator according to an exemplary embodiment of the present disclosure.

FIG. 2 is a block diagram schematically illustrating a schematic configuration of a laser oscillator.

FIG. 3 is a circuit configuration diagram schematically illustrating an electric circuit configuration of a laser oscillator.

FIG. 4 is a first graph showing a known relationship among a discharge time, a preliminary-charge time, and residual voltage in a capacitor.

FIG. 5 is an enlarged view of part V in FIG. 4.

FIG. 6 is a second graph showing a known relationship between a discharge time and a required preliminary-charge time in a capacitor.

### DESCRIPTION OF EMBODIMENT

Hereinafter, exemplary embodiments of the present disclosure will be described in detail with reference to the drawings. The following description of preferable exemplary embodiments is merely illustrative in nature and is not intended to limit the present disclosure, application thereof, or use thereof.

### (Laser Processing System)

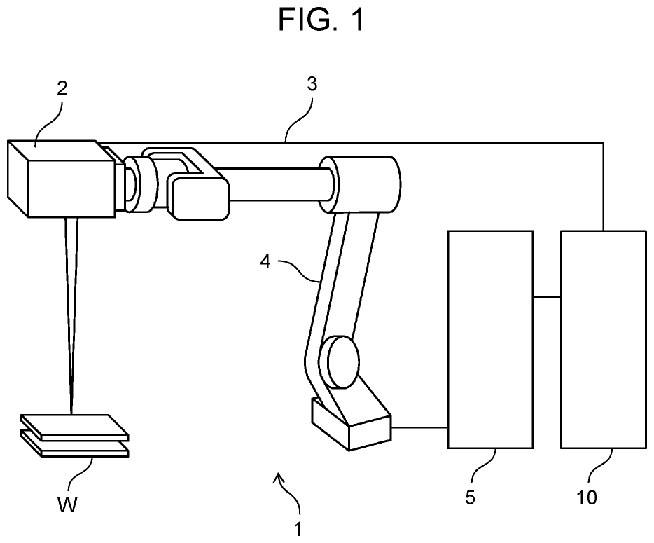

FIG. 1 illustrates laser processing system (laser processing apparatus) 1 according to the present exemplary embodiment. Laser processing system 1 is introduced into a production line of an automobile, for example, and performs laser processing such as cutting, welding, and punching of workpiece W.

Laser processing system 1 includes laser oscillator 10, laser irradiation head 2, optical fiber 3, manipulator 4, and controller 5.

Laser oscillator 10 is a device for oscillating a laser beam. The laser beam emitted (output) from laser oscillator 10 is guided to laser irradiation head 2 through optical fiber 3. Laser irradiation head 2 irradiates workpiece W with the laser beam.

Laser irradiation head 2 is attached to a leading end of manipulator 4 that moves laser irradiation head 2. Controller 5 controls operation of manipulator 4 and oscillation of the laser beam with laser oscillator 10. Controller 5 may be remotely operated using a remote controller or the like.

When manipulator 4 is operated while laser irradiation head 2 irradiates workpiece W with a laser beam, workpiece W is irradiated with the laser beam in a desired trajectory, thereby performing laser processing on workpiece W.

When laser oscillator 10 oscillates a laser beam, strong light is emitted. Thus, laser processing system 1 is installed in a dedicated work room (not illustrated) partitioned from surroundings. The laser processing step allows processed workpiece W to be carried out from the work room every time one workpiece W is machined (for each processing), and unprocessed workpiece W to be carried into the work room. At this time, a door of the work room needs to be opened and closed.

From the viewpoint of ensuring safety, laser oscillator 10 needs to be emergently stopped every time the door is opened and closed, or for each processing. To recover laser oscillator 10 from the emergency stop, a capacitor incorporated in a drive power source described later in laser oscillator 10 needs to be preliminarily charged.

### (Configuration of Laser Oscillator)

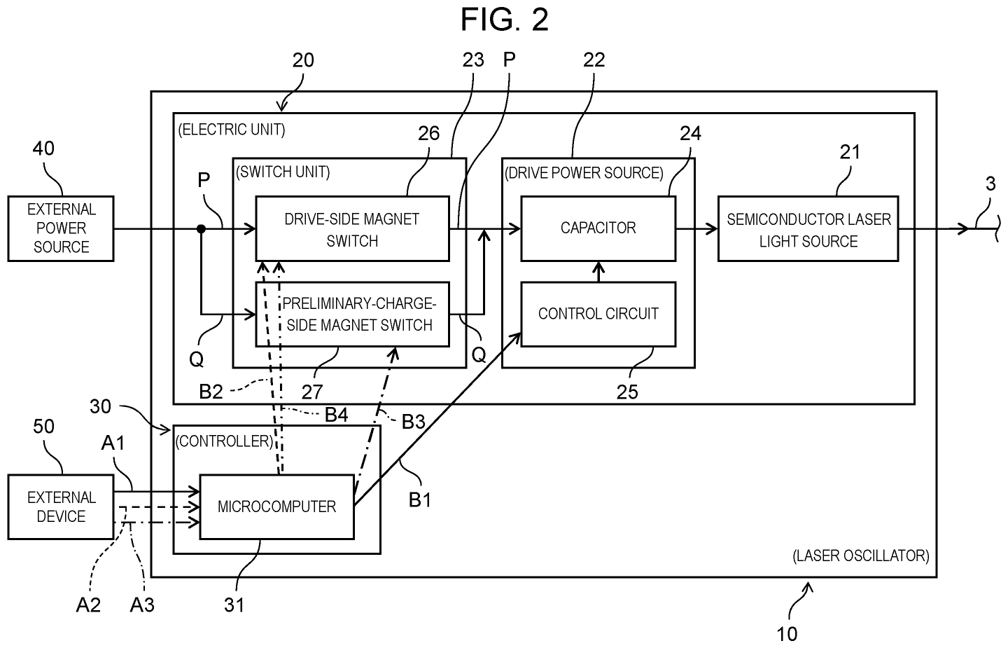

FIG. 2 illustrates a schematic configuration of laser oscillator 10. Laser oscillator 10 includes electric unit 20 and controller 30. Electric unit 20 is driven by power supplied from external power source (switch board) 40 to oscillate a laser beam. Controller 30 controls electric unit 20 based on a command from external device 50. For example, controller 5 illustrated in FIG. 1 can be applied as external device 50. Controller 30 receives command signal (external signal) A from external device 50 and transmits control signal B to electric unit 20 using built-in microcomputer 31.

Examples of command signal A include laser beam emission signal A1, emergency stop signal A2, and emergency-stop release signal A3, which will be described later. Examples of control signal B include close signal B1, open signal B2, close signal B3, close signal B4, and the like, which will be described later.

Electric unit 20 of laser oscillator 10 includes semiconductor laser light source 21, drive power source 22, and switch unit 23.

Semiconductor laser light source 21 emits a laser beam. Semiconductor laser light source 21 includes multiple semiconductor laser diode elements and a condenser lens. Laser beams oscillated in the respective elements are condensed by the condenser lens and emitted.

Drive power source 22 incorporates a rectifier circuit (not illustrated) and capacitor 24 constituting a smoothing circuit. Drive power source 22 includes capacitor 24 to which alternating-current voltage (current) is supplied from external power source 40. The AC voltage supplied from external power source 40 is converted into a pulsating current in the rectifier circuit inside drive power source 22, and is further smoothed by capacitor 24 as a smoothing circuit to be in a state close to a direct current. Capacitor 24 is charged by storing charges in its pole plate to obtain predetermined voltage.

Based on voltage of capacitor 24 charged, drive power source 22 drives semiconductor laser light source 21 by applying the voltage to semiconductor laser light source 21. When semiconductor laser light source 21 is driven, a laser beam is emitted. Semiconductor laser light source 21 is connected at its leading end part to optical fiber 3.

Semiconductor laser light source 21 is not driven only by charging capacitor 24 of drive power source 22. Semiconductor laser light source 21 is driven (emits a laser beam) by operation (closing) of control circuit 25 provided in drive power source 22.

Controller 30 switches control circuit 25 based on a laser beam emission command from external device 50. Specifically, controller 30 causes microcomputer 31 to receive laser beam emission signal Al from external device 50 and transmit close signal B1 to control circuit 25.

When a laser beam is emitted, voltage of capacitor 24 slightly decreases. However, the voltage of capacitor 24 is recovered immediately because voltage is always supplied from external power source 40 to capacitor 24 while semiconductor laser light source 21 is driven. Thus, capacitor 24 is considered to be always constant in voltage when semiconductor laser light source 21 is driven.

Switch unit 23 is interposed between external power source 40 and drive power source 22. Switch unit 23 switches a voltage supply state from supply from external power source 40 to supply from capacitor 24 of drive power source 22. Switching of switch unit 23 is controlled by controller 30.

External power source 40 and drive power source 22 are connected by two circuits that are in parallel to each other and that include drive-side circuit P and preliminary-charge-side circuit Q. Drive-side circuit P is configured to drive semiconductor laser light source 21. Preliminary-charge-side circuit Q is configured to preliminarily charge capacitor 24 of drive power source 22 to recover laser oscillator 10 from an emergency stop.

Switch unit 23 includes drive-side magnet switch (drive-side electromagnetic switch) 26 and preliminary-charge-side magnet switch (preliminary-charge-side electromagnetic switch) 27. Drive-side magnet switch 26 opens and closes drive-side circuit P. Then, preliminary-charge-side magnet switch 27 opens and closes preliminary-charge-side circuit Q.

When at least one of drive-side circuit P and preliminary-charge-side circuit Q is closed, external power source 40 supplies voltage to capacitor 24. In contrast, when both drive-side circuit P and preliminary-charge-side circuit Q are open, external power source 40 supplies no voltage to capacitor 24.

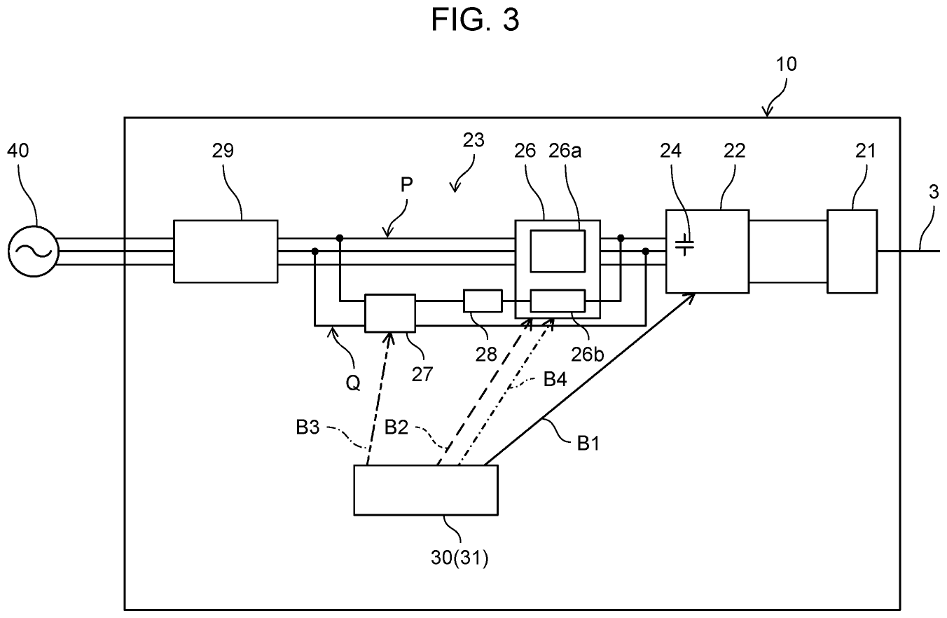

FIG. 3 illustrates an electric circuit configuration of laser oscillator 10. External power source 40 is a three-phase AC power source in which single-phase ACs of three respective systems shifted in phase by 120 degrees are combined.

External power source 40 and drive power source 22 are connected to each other in drive-side circuit P with an electric wire via drive-side magnet switch 26 in all of the three phases. AC voltage supplied by the three phases passes through the rectifier circuit to be supplied to both pole plate sides of capacitor 24 serving as a smoothing circuit.

External power source 40 and drive power source 22 are connected to each other in the preliminary-charge-side circuit Q with an electric wire via preliminary-charge-side magnet switch 27 in only two of the three phases. Preliminary-charge-side circuit Q is provided with resistor 28 in one phase. Preliminary-charge-side circuit Q may include all three phases. Preliminary-charge-side circuit Q may be provided with resistor 28 in each of multiple phases. Between external power source 40 and switch unit 23, breaker 29 is interposed (see FIG. 3, not illustrated in FIG. 2).

More specifically, drive-side magnet switch 26 is provided with main contact 26a and b-contact 26b as illustrated in FIG. 3. Main contact 26a is used to open and close drive-side circuit P. Then, b-contact 26b is used to open and close preliminary-charge-side circuit Q. When main contact 26a closes drive-side circuit P, b-contact 26b simultaneously opens preliminary-charge-side circuit Q.

Controller 30 performs mode switching among drive mode X1 in which semiconductor laser light source 21 is drivable, preliminary-charge mode X2 in which capacitor 24 of drive power source 22 is preliminarily charged, and emergency-stop mode X3 in which voltage supply from external power source 40 to capacitor 24 of drive power source 22 is stopped.

More specifically, “drive mode X1” refers to a state in which preliminary charging of capacitor 24 has already been completed, and semiconductor laser light source 21 can be driven (emission of a laser beam is enabled). For example, the present exemplary embodiment enables semiconductor laser light source 21 to be driven (a laser beam to be emitted) at any time by closing control circuit 25 in drive power source 22 in drive mode X1.

More specifically, “preliminary-charge mode X2” refers to a state in which only capacitor 24 is charged without driving semiconductor laser light source 21 (emission of a laser beam) when laser oscillator 10 is recovered from an emergency stop.

Controller 30 may be connected to a display (not illustrated) to display mode X1, X2, or X3 in operation on the display. Specific aspects of respective modes X1, X2, and X3 will be described later.

### (Relationship Between Discharge Time and Required Preliminary-Charge Time in Capacitor)

Controller 30 stores (has) model M representing a known relationship between discharge time Ta of capacitor 24 and required preliminary-charge time Tb of capacitor 24. Discharge time Ta is equivalent to an elapsed time after voltage supply from external power source 40 to capacitor 24 is stopped (after emergency-stop mode X3 is started). required preliminary-charge time Tb is a time required for capacitor 24 to obtain a shortage of voltage (undervoltage) Vb required to drive semiconductor laser light source 21 when arbitrary discharge time Ta elapses.

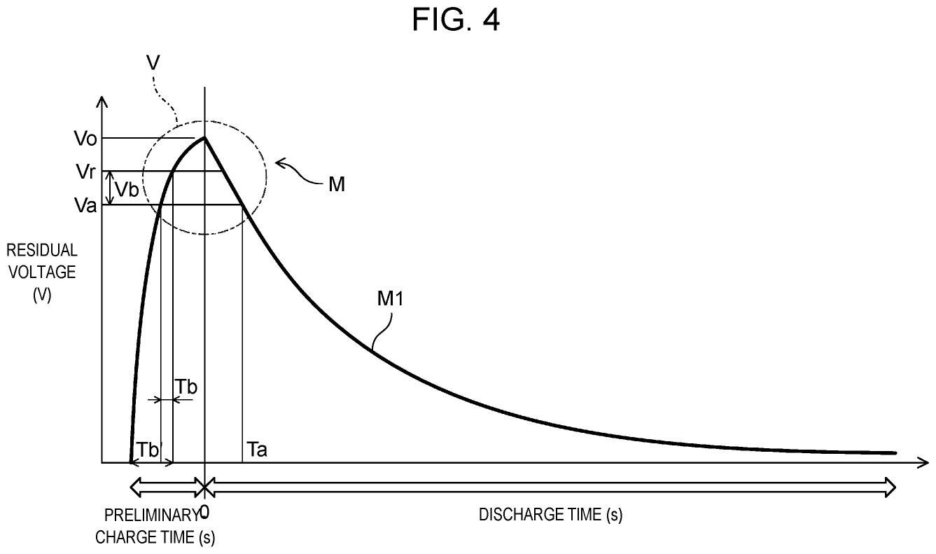

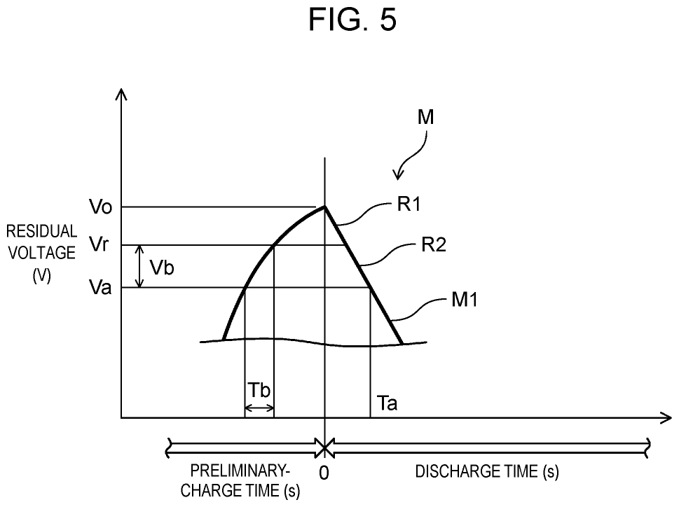

Model M will be described below. FIG. 4 is first graph M1 showing a known relationship among discharge time (s), preliminary-charge time (s), and residual voltage (V) in capacitor 24. FIG. 5 is an enlarged view of part V in FIG. 4. First graph M1 is an aspect of model M. The horizontal axis represents discharge time (s) and preliminary-charge time (s) in capacitor 24, and the vertical axis represents residual voltage (V) of capacitor 24. First graph M1 is prepared in advance by experiments or numerical simulations.

As shown in FIG. 4, residual voltage (V) is maximum when discharge time (s) is zero, and decreases as discharge time (s) elapses. Residual voltage (V) increases as preliminary-charge time (s) elapses. FIG. 4 shows first graph M1 within a range of several tens of minutes from start of discharge.

FIGS. 4 and 5 each indicate Ta representing an arbitrary discharge time, Va representing residual voltage at arbitrary discharge time Ta, Vo representing maximum voltage chargeable to capacitor 24, Vr representing voltage (required voltage) necessary for driving semiconductor laser light source 21, Vb representing a shortage of voltage (undervoltage) required to drive semiconductor laser light source 21 at arbitrary discharge time Ta, and Tb representing a required preliminary-charge time at arbitrary discharge time Ta. As shown in FIGS. 4 and 5, required preliminary-charge time Tb can be derived from discharge time Ta using first graph M1. Required voltage Vr is 80% to 100% of maximum voltage Vo, for example.

FIG. 5 shows first graph M1 within a range of several 10 seconds (e.g., a discharge time is 0 s to 30 s) from start of discharge in an enlarged manner. As shown in FIG. 5, although residual voltage (V) decreases as discharge time (s) elapses within range R1 immediately after the start of discharge (e.g., the discharge time is 0 s to 10 s), residual voltage (V) is equal to or higher than required voltage Vr. In contrast, residual voltage (V) further decreases as discharge time (s) elapses within range R2 after elapse for a while from the start of discharge (e.g., the discharge time is 10 s to 30 s), and thus results in being equal to or less than required voltage Vr.

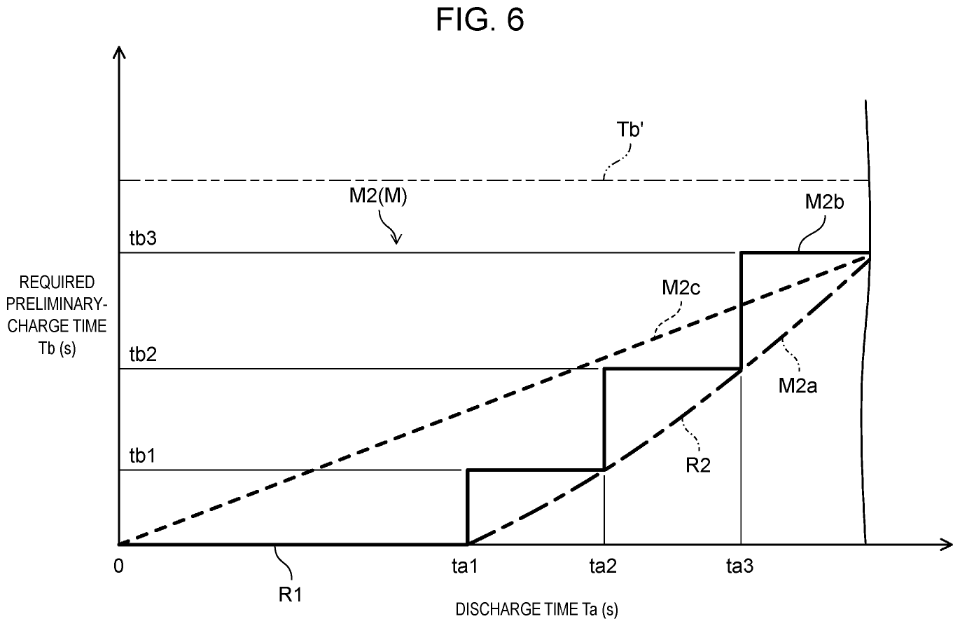

FIG. 6 is second graph M2 showing a known relationship between discharge time Ta (s) and required preliminary-charge time Tb (s) in capacitor 24. Second graph M2 is an aspect of model M. Second graph M2 shown in FIG. 6 corresponds to first graph M1 shown in the enlarged view of FIG. 5. That is, FIG. 6 shows second graph M2 within the range of several 10 seconds (e.g., the discharge time is 0 s to 30 s) from the start of discharge. The horizontal axis represents discharge time Ta (s) of capacitor 24, and the vertical axis represents required preliminary-charge time Tb (s) of capacitor 24. As shown in FIG. 6, required preliminary-charge time Tb is a function of discharge time Ta.

Second graph M2 is exactly represented by curve M2a as indicated by an alternate long and short dash line in FIG. 6. Curve M2a is obtained by directly transferring the relationship between discharge time Ta and required preliminary-charge time Tb in the enlarged view of FIG. 5.

As shown in FIG. 6, residual voltage Va is equal to or higher than required voltage Vr as described above within range R1 immediately after the start of discharge (e.g., the discharge time is 0 s to 10 s), so that required preliminary-charge time Tb is zero and constant regardless of elapse of discharge time Ta. In contrast, residual voltage Va is equal to or less than required voltage Vr as described above within range R2 after elapse for a while from the start of discharge (e.g., the discharge time is 10 s to 30 s), so that required preliminary-charge time Tb increases as discharge time Ta elapses.

Second graph M2 (model M) shows the relationship between discharge time Ta and required preliminary-charge time Tb with function M2b (solid line) in a stepwise shape.

As illustrated in FIG. 6, function M2b in a stepwise shape shows required preliminary-charge time Tb that is uniformly zero when discharge time Ta is from zero to ta1. When discharge time Ta is from ta1 to ta2, required preliminary-charge time Tb is uniformly tb1. When discharge time Ta is from ta2 to ta3, required preliminary-charge time Tb is uniformly tb2. When discharge time Ta is from ta3 to ta4 (not shown), required preliminary-charge time Tb is uniformly tb3. The same applies hereinafter.

### (Control Mode of Laser Oscillator)

Hereinafter, a control mode of the laser oscillator 10 will be described mainly with reference to FIG. 2.

Drive mode X1 causes drive-side circuit P (drive-side magnet switch 26) to be closed, and preliminary-charge-side circuit Q (preliminary-charge-side magnet switch 27) to be opened. As a result, drive-side circuit P allows external power source 40 to constantly supply voltage to capacitor 24 of drive power source 22. Drive mode X1 enables semiconductor laser light source 21 to be driven (emission of a laser beam) because preliminary charge of capacitor 24 is already completed.

Specifically, drive mode X1 allows controller 30 to cause microcomputer 31 to close control circuit 25 by not only receiving laser beam emission signal A1 from external device 50 but also transmitting close signal B1 to control circuit 25 in drive power source 22. As a result, voltage of capacitor 24 is applied to semiconductor laser light source 21, and semiconductor laser light source 21 is driven, or emits a laser beam.

As described above, laser oscillator 10 (more specifically, electric unit 20 of laser oscillator 10) needs to be emergently stopped for each processing.

To emergently stop laser oscillator 10, controller 30 performs mode switching from drive mode X1 to emergency-stop mode X3. Specifically, controller 30 not only receives emergency stop signal A2 from external device 50, but also transmits open signal B2 to drive-side magnet switch 26 in switch unit 23. As a result, drive-side circuit P (drive-side magnet switch 26) is opened. Then, preliminary-charge-side circuit Q (preliminary-charge-side magnet switch 27) is still opened.

emergency-stop mode X3 allows external power source 40 to supply no voltage to capacitor 24 of drive power source 22. As a result, residual voltage Va of capacitor 24 decreases as discharge time Ta elapses due to discharge (see FIGS. 4 and 5).

Although not illustrated, controller 30 is connected to external power source 40 with a circuit different from drive-side circuit P and preliminary-charge-side circuit Q, or is driven by an electric system different from external power source 40, and thus is not stopped even in emergency-stop mode X3.

When preparation such as replacement of workpiece W is completed and the emergency stop can be released, controller 30 receives emergency-stop release signal A3 from external device 50. When receiving emergency-stop release signal A3, controller 30 first derives required preliminary-charge time Tb from discharge time Ta based on model M, or function M2b in a stepwise shape (see FIG. 6). At this time, discharge time Ta is equivalent to a time from when controller 30 receives emergency stop signal A2 to when controller 30 receives emergency-stop release signal A3.

When receiving emergency-stop release signal A3, controller 30 secondly performs mode switching from emergency-stop mode X3 to preliminary-charge mode X2. Specifically, controller 30 transmits close signal B3 to preliminary-charge-side magnet switch 27 in switch unit 23. As a result, preliminary-charge-side circuit Q (preliminary-charge-side magnet switch 27) is closed. Then, drive-side circuit P (drive-side magnet switch 26) is still opened.

Preliminary-charge mode X2 allows external power source 40 to supply voltage to capacitor 24 of drive power source 22 with preliminary-charge-side circuit Q. As a result, capacitor 24 is preliminarily charged. Then, residual voltage Va of capacitor 24 increases with elapse of time due to the preliminary charge (see FIGS. 4 and 5).

Controller 30 maintains preliminary-charge mode X2 until required preliminary-charge time Tb elapses after performing mode switching from emergency-stop mode X3 to preliminary-charge mode X2. As a result, capacitor 24 of drive power source 22 is sufficiently charged until undervoltage Vb at discharge time Ta is obtained (see FIGS. 4 and 5).

Controller 30 may be configured not to transmit close signal B1 to control circuit 25 in drive power source 22 even when laser beam emission signal A1 is received from external device 50 in preliminary-charge mode X2.

Controller 30 is configured to perform mode switching from preliminary-charge mode X2 to drive mode X1 after required preliminary-charge time Tb elapses, more specifically, immediately after the elapse, after mode switching from emergency-stop mode X3 to preliminary-charge mode X2 is performed.

Here, the phase, “immediately after required preliminary-charge time Tb elapses”, refers to a time at which required preliminary-charge time Tb elapses or a time after about ten seconds elapse from the elapsed time (about zero to ten seconds after the time at which required preliminary-charge time Tb elapses).

Specifically, controller 30 transmits close signal B4 to drive-side magnet switch 26 in switch unit 23 immediately after required preliminary-charge time Tb elapses after the mode switching from emergency-stop mode X3 to preliminary-charge mode X2 is performed. As a result, main contact 26a of drive-side magnet switch 26 is closed, and then b-contact 26b is simultaneously opened. That is, preliminary-charge-side circuit Q is simultaneously opened when drive-side circuit P is closed (see FIG. 3).

Controller 30 automatically transmits close signal B4 using microcomputer 31 immediately after required preliminary-charge time Tb elapses without receiving a command signal from external device 50. That is, when receiving emergency-stop release signal A3 from external device 50, controller 30 automatically derives required preliminary-charge time Tb from discharge time Ta based on model M, performs mode switching from emergency-stop mode X3 to preliminary-charge mode X2, and performs mode switching from preliminary-charge mode X2 to drive mode X1 immediately after required preliminary-charge time Tb elapses.

### (Effect of Operation)

Conventional configurations allow preliminary-charge time Tb′ when laser oscillator 10 is recovered from an emergency stop to be set to a constant value based on residual voltage Va of capacitor 24 that is zero regardless of discharge time Ta (see FIGS. 4 and 6). That is, the conventional configurations allow preliminary-charge time Tb′ to be secured longer than a time (required preliminary-charge time Tb) required to obtain a shortage of voltage Vb required to drive semiconductor laser light source 21 as shown in FIGS. 4 and 6, and preliminary-charge time Tb′ is excessively long particularly when discharge time Ta is short (when required preliminary-charge time Tb is short).

The present exemplary embodiment allows required preliminary-charge time Tb to derived from discharge time Ta based on model M. The present exemplary embodiment then allows mode switching from preliminary-charge mode X2 to drive mode X1 to be performed after required preliminary-charge time Tb elapses (e.g., immediately after the elapse) after mode switching from emergency-stop mode X3 to preliminary-charge mode X2 is performed.

When preliminary-charge mode X2 can be shifted to drive mode X1 after elapse of required preliminary-charge time Tb less than conventional preliminary-charge time Tb′ as described above, time of preliminary-charge mode X2 can be shortened to quickly drive semiconductor laser light source 21 as compared with the conventional configurations.

As described above, recovery time from an emergency stop of laser oscillator 10 can be shortened.

To achieve the effect above, a large-scale device or the like is not required to be prepared, and thus simplifying a configuration.

When model M (graph M2) is represented by function M2b in a stepwise shape, calculation of deriving required preliminary-charge time Tb from discharge time Ta is simplified as compared with model M that is represented directly by curve M2a. Additionally, the amount of data stored in controller 30 can be reduced.

When laser oscillator 10 according to the present exemplary embodiment is applied to laser processing system 1, a cycle time of a laser processing step can be shortened.

In particular in the field of automobile manufacturing, an advantageous cost reduction effect can be obtained even with a time reduction on the order of seconds.

### Other Exemplary Embodiments

Although the present disclosure has been described with reference to preferable exemplary embodiments, the present disclosure is not limited to the above description, and various modifications can be surely made.

For example, the relationship between discharge time Ta and required preliminary-charge time Tb may be represented by linear function (direct function) M2c in model M (graph M2) as indicated by a broken line in FIG. 6.

When the relationship is represented by linear function M2c, the calculation can be further simplified as compared with a case of directly using curve M2a or a case of being represented by function M2b in a stepwise shape.

Although the present exemplary embodiment allows controller 30 to perform mode switching from emergency-stop mode X3 to preliminary-charge mode X2 after deriving required preliminary-charge time Tb from discharge time Ta based on model M, the present invention is not limited thereto. Controller 30 may derive required preliminary-charge time Tb from discharge time Ta based on model M immediately after the mode switching from emergency-stop mode X3 to preliminary-charge mode X2 is performed. Controller 30 also may derive required preliminary-charge time Tb from discharge time Ta based on model M, and simultaneously perform the mode switching from emergency-stop mode X3 to preliminary-charge mode X2.

Although external power source 40 and drive power source 22 are connected by drive-side circuit P and preliminary-charge-side circuit Q that are in parallel to each other in the present exemplary embodiment, the present invention is not limited thereto. External power source 40 and drive power source 22 may be connected by one circuit used for both drive and preliminary charge.

### INDUSTRIAL APPLICABILITY

The present disclosure is extremely useful because it can be applied to a laser oscillator.

### REFERENCE MARKS IN THE DRAWINGS

M model
M2b function in stepwise shape
M2c linear function
Ta discharge time
Tb required preliminary-charge time
Vo maximum voltage
Vr required voltage
Va residual voltage
Vb undervoltage
W workpiece
P drive-side circuit
Q preliminary-charge-side circuit
1 laser processing system
2 laser irradiation head
10 laser oscillator
21 semiconductor laser light source
22 drive power source
23 switch unit
24 capacitor
26 drive-side magnet switch
27 preliminary-charge-side magnet switch
30 controller
40 external power source

1. A laser oscillator comprising:
a semiconductor laser light source that emits a laser beam;
a drive power source that includes a capacitor to which voltage is supplied from an external power source, and that drives the semiconductor laser light source with voltage of the capacitor charged;
a switch unit that switches a voltage supply state from the external power source to the capacitor; and
a controller that controls switching of the switch unit,
wherein
the controller performs mode switching among a drive mode in which the semiconductor laser light source is drivable, a preliminary-charge mode in which the capacitor is preliminarily charged, and a stop mode in which supply of voltage from the external power source to the capacitor is stopped,
the controller has a model showing a known relationship between a discharge time that is an elapsed time from stop of supply of voltage from the external power source to the capacitor and a required preliminary-charge time that is required for the capacitor to obtain a shortage of voltage required to drive the semiconductor laser light source, and
the controller derives the required preliminary-charge time from the discharge time based on the model to perform mode switching from the stop mode to the preliminary-charge mode, and then performs mode switching from the preliminary-charge mode to the drive mode after the required preliminary-charge time elapses.

2. The laser oscillator according to claim 1, wherein the model shows a relationship between the discharge time and the required preliminary-charge time, the relationship being represented by a function in a stepwise shape.

3. The laser oscillator according to claim 1, wherein the model shows a relationship between the discharge time and the required preliminary-charge time, the relationship being represented by a linear function.

4. A laser processing system comprising:
the laser oscillator according to claim 1; and
a laser irradiation head that irradiates a workpiece with a laser beam emitted from the laser oscillator.
